(19) United States
(12) Patent Application Publication
(10) Pub. No.: US 2025/0335347 A1
(43) Pub. Date: Oct. 30, 2025

(54) MEMORY DEVICE, TRIM REGISTER, MEMORY SYSTEM, AND ELECTRONIC APPARATUS

(71) Applicant: Yangtze Memory Technologies Co., Ltd., Wuhan (CN)

(72) Inventors: Xiaodong Mei, Wuhan (CN); Huangpeng Zhang, Wuhan (CN); Simin Zhang, Wuhan (CN); Xiang Fu, Wuhan (CN)

(21) Appl. No.: 19/012,049

(22) Filed: Jan. 7, 2025

(30) Foreign Application Priority Data
Apr. 28, 2024 (CN) 202410525519.5

(51) Int. Cl. G06F 12/02

(52) U.S. Cl. CPC G06F 12/0223

(57) ABSTRACT

Examples of the present disclosure disclose a memory device, a trim register, a memory system, and an electronic apparatus. The memory device includes a programmable memory circuit configured to store a plurality of trim information; and a first trim register coupled with the programmable memory circuit and including a dynamic latch circuit, wherein the first trim register is configured to load a first trim information of the plurality of trim information from the programmable memory circuit in response to the memory device entering a working mode; and latch the first trim information to the dynamic latch circuit.

### CROSS-REFERENCE TO RELATED APPLICATIONS

This application claims the benefit of priority to Chinese Application No. 202410525519.5, filed on Apr. 28, 2024, which is incorporated herein by reference in its entirety.

### TECHNICAL FIELD

Examples of the present disclosure relate to the technical field of memory device, and relate to, but are not limited to, a memory device, a trim register, a memory system, and an electronic apparatus.

### BACKGROUND

Memories are classified into volatile memories and non-volatile memories depending on whether stored data is retained in the case of a power failure. The volatile memories that lose data in the case of a power failure may comprise a Static Random Access Memory (SRAM) and a Dynamic Random Access Memory (DRAM).

### SUMMARY

According to a first aspect of examples of the present disclosure, a memory device is provided, comprising: a programmable memory circuit configured to store a plurality of trim information; and a first trim register coupled with the programmable memory circuit and comprising a dynamic latch circuit, wherein the first trim register is configured to: load a first trim information of the plurality of trim information from the programmable memory circuit in response to the memory device entering a working mode; and latch the first trim information to the dynamic latch circuit.

In some examples, the memory device further comprises: a control logic circuit coupled with the first trim register and configured to: generate an initialization signal in response to the memory device entering the working mode, the first trim register further comprises an initialization circuit coupled with the dynamic latch circuit and configured to: initialize the dynamic latch circuit in response to the initialization signal.

In some examples, the control logic circuit is further configured to: generate a reset signal in response to the memory device entering the working mode; the first trim register further comprises a reset circuit coupled with the dynamic latch circuit and configured to: reset the dynamic latch circuit in response to the reset signal prior to initializing the dynamic latch circuit.

In some examples, the dynamic latch circuit comprises a first inverter and a second inverter, an output end of the first inverter is coupled with an input end of the second inverter, and an output end of the second inverter is coupled with an input end of the first inverter; the initialization circuit comprises a first transistor, a first end of the first transistor is coupled with the output end of the first inverter, a second end of the first transistor is coupled with a first supply end, and a control end of the first transistor is configured to receive the initialization signal.

In some examples, the initialization circuit further comprises a second transistor, a first end of the second transistor is coupled with the output end of the first inverter, a second end of the second transistor is coupled with the first end of the first transistor, and a control end of the second transistor is configured to receive an initialization drive signal.

In some examples, the reset circuit comprises a third transistor, a first end of the third transistor is coupled with the input end of the first inverter, a second end of the third transistor is coupled with a second supply end, and a control end of the third transistor is configured to receive the reset signal.

In some examples, the first trim register is further configured to: load a test trim information from the control logic circuit in response to the memory device entering a test mode; and latch the test trim information to the dynamic latch circuit.

In some examples, the memory device comprises a plurality of first trim registers, wherein the control logic circuit is further configured to: generate an address signal and a test control signal in response to the memory device entering the test mode; the first trim register further comprises an address selection circuit configured to: select at least one first trim register from the plurality of first trim registers in response to the address signal; and latch the test trim information to the dynamic latch circuit of the selected first trim register in response to the test control signal.

In some examples, the dynamic latch circuit comprises a first inverter and a second inverter, an output end of the first inverter is coupled with an input end of the second inverter, and an output end of the second inverter is coupled with an input end of the first inverter; the address selection circuit comprises a fourth transistor, a fifth transistor, and a sixth transistor, a first end of the fourth transistor is coupled with the input end of the first inverter, a first end of the fifth transistor is coupled with the output end of the first inverter, a second end of the fourth transistor is coupled with a second end of the fifth transistor, and a control end of the fourth transistor or a control end of the fifth transistor is configured to receive the test control signal; a first end of the sixth transistor is coupled with a coupling node between the second end of the fourth transistor and the second end of the fifth transistor, a second end of the sixth transistor is coupled with a third supply end, and a control end of the sixth transistor is configured to receive the address signal.

In some examples, the memory device further comprises: a second trim register coupled with the programmable memory circuit and comprising a set-reset latch circuit, wherein the second trim register is configured to: load a second trim information of the plurality of trim information from the programmable memory circuit in response to the memory device entering the working mode; and latch the second trim information to the set-reset latch circuit.

In some examples, an area of the first trim register is less than an area of the second trim register.

In some examples, the memory device comprises a dynamic random access memory.

According to a second aspect of examples of the present disclosure, a trim register is provided, the trim register comprising: a reset circuit, an initialization circuit, and a dynamic latch circuit, wherein the reset circuit and the initialization circuit are coupled with the dynamic latch circuit respectively; the reset circuit is configured to: reset the dynamic latch circuit; the initialization circuit is configured to: initialize the dynamic latch circuit, until a loaded trim information is latched to the dynamic latch circuit; the dynamic latch circuit is configured to: latch the trim information.

In some examples, the dynamic latch circuit comprises a first inverter and a second inverter, an output end of the first inverter is coupled with an input end of the second inverter, and an output end of the second inverter is coupled with an input end of the first inverter; the initialization circuit comprises a first transistor, a first end of the first transistor is coupled with the output end of the first inverter, a second end of the first transistor is coupled with a first supply end, and a control end of the first transistor is configured to receive an initialization signal.

In some examples, the initialization circuit further comprises a second transistor, a first end of the second transistor is coupled with the output end of the first inverter, a second end of the second transistor is coupled with the first end of the first transistor, and a control end of the second transistor is configured to receive an initialization drive signal.

In some examples, the reset circuit comprises a third transistor, a first end of the third transistor is coupled with the input end of the first inverter, a second end of the third transistor is coupled with a second supply end, and a control end of the third transistor is configured to receive a reset signal.

In some examples, the trim register further comprises an address selection circuit configured to: select the trim register; and latch a test trim information to the dynamic latch circuit of the selected trim register.

In some examples, the address selection circuit comprises a fourth transistor, a fifth transistor, and a sixth transistor, a first end of the fourth transistor is coupled with the input end of the first inverter, a first end of the fifth transistor is coupled with the output end of the first inverter, a second end of the fourth transistor is coupled with a second end of the fifth transistor, and a control end of the fourth transistor or a control end of the fifth transistor is configured to receive a test control signal; a first end of the sixth transistor is coupled with a coupling node between the second end of the fourth transistor and the second end of the fifth transistor, a second end of the sixth transistor is coupled with a third supply end, and a control end of the sixth transistor is configured to receive an address signal.

In some examples, the trim register further comprises a data output circuit configured to: output the trim information.

In some examples, the data output circuit comprises at least one third inverter.

According to a third aspect of examples of the present disclosure, a memory system is provided, comprising:

one or more memory devices as described in any example in the first aspect of examples of the present disclosure; and

a memory controller coupled to the one or more memory devices and configured to control the one or more memory devices.

According to a fourth aspect of examples of the present disclosure, an electronic apparatus is provided, comprising the memory system as described in the third aspect of examples of the present disclosure.

In the examples of the present disclosure, by configuring the first trim register to comprise the dynamic latch circuit, the first trim register may load the first trim information of a plurality of trim information from the programmable memory circuit when the memory device enters the working mode, and latch the loaded first trim information to the dynamic latch circuit, thereby achieving a fast access of the first trim information. Furthermore, as the area of a dynamic latch is small, a circuit structure of the first trim register may be optimized, and the area of the first trim register may be reduced, which is favorable to further miniaturization of the size of the memory device.

### BRIEF DESCRIPTION OF THE DRAWINGS

In the accompanying drawings, unless otherwise specified, identical or similar components or elements are represented by a like numeral throughout several drawings. These drawings are not necessarily drawn to scale. It is to be understood that, these drawings merely describe some implementations disclosed according to examples of the present application, and should not be considered as limiting the scope of the present application.

FIG. 1 is a schematic distribution diagram illustrating a memory device according to examples of the present disclosure.

FIG. 2 is a schematic diagram illustrating a trim register according to examples of the present disclosure.

FIG. 3 is a schematic block diagram illustrating a memory device according to examples of the present disclosure.

FIG. 4 is a schematic block diagram illustrating a first trim register according to examples of the present disclosure.

FIG. 5 is a schematic circuit diagram illustrating the first trim register according to examples of the present disclosure.

FIG. 6a and FIG. 6b are schematic diagrams illustrating latching of a trim information to a dynamic latch circuit in a working mode according to examples of the present disclosure.

FIG. 7a to FIG. 7c are schematic diagrams illustrating latching of a trim information to a dynamic latch circuit in a test mode according to examples of the present disclosure.

FIG. 8 is a flow diagram illustrating an operation method of a memory device according to examples of the present disclosure.

FIG. 9 is a diagram illustrating an operation timing of a memory device according to examples of the present disclosure.

FIG. 10 is a schematic block diagram illustrating an electronic apparatus according to examples of the present disclosure.

### DETAILED DESCRIPTION

For ease of understanding of the present disclosure, example implementations of the present disclosure will be described below in more detail with reference to the relevant drawings. Although the example implementations of the present disclosure are shown in the drawings, it is to be understood that the present disclosure may be achieved in various forms which should not be limited by particular implementations as set forth herein. Rather, these implementations are provided for a more thorough understanding of the present disclosure, and can fully convey the scope of the present disclosure to those skilled in the art.

In the following description, numerous specific details are presented to provide a more thorough understanding of the present disclosure. However, it is apparent to those skilled in the art that the present disclosure may be implemented without one or more of these details. In some examples, in order to avoid confusing with the present disclosure, some technical features well-known in the art are not described; that is, not all features of actual examples are described herein, and well-known functions and structures are not described in detail.

In general, terminologies may be understood at least in part from usage in the context. For example, the term “one or more” as used herein, depending at least in part upon the context, can be used to describe any feature, structure, or characteristic in a singular sense or can be used to describe combinations of features, structures, or characteristics in a plural sense. Similarly, terms, such as “a/an” or “the”, likewise can be understood as conveying a singular use or a plural use, depending at least in part upon the context. In addition, the term “based on” may be understood as being not necessarily intended to convey an exclusive set of factors and may, instead, allow for existence of additional factors not necessarily described expressly, likewise depending at least in part upon the context.

The terms as used herein are only intended to describe the particular examples, and are not used as limitations to the present disclosure, unless otherwise defined. As used herein, unless otherwise indicated expressly in the context, “a/an”, “one” and “the” in a singular form are also intended to include a plural form. It is also to be understood that terms “consist of” and/or “comprise”, when used in this specification, determine the presence of described features, integers, steps, operations, elements and/or components, but do not preclude the presence or addition of one or more of other features, integers, steps, operations, elements, components, and/or groups. As used herein, the term “and/or” comprises any and all combinations of related items listed.

In order to understand the present disclosure thoroughly, detailed operations and detailed structures will be proposed in the following description to set forth the technical solution of the present disclosure. The detailed descriptions of the preferable examples of the present disclosure are as follows. However, the present disclosure may also have other implementations in addition to these detailed descriptions.

After the memory has been manufactured, the impacts of process deviations, layout errors, etc. on the memory may be adjusted through trim tests, so as to improve the performance of the memory. For example, the memory may adjust operating parameters of the memory by accessing trim information registered in a trim register.

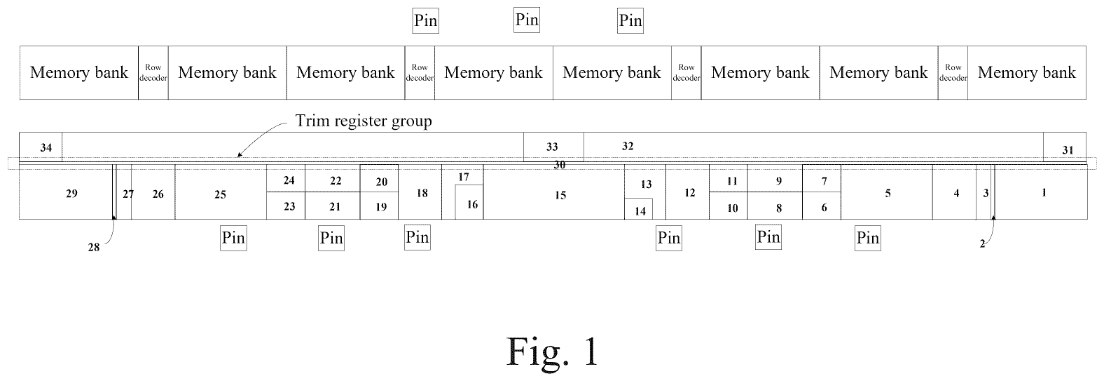

A trim information obtained after a trim test of a memory device may be written to the interior of the memory device and loaded to a respective trim register when the memory device is powered on. However, a large area of the trim register is not favorable to further miniaturization of the size of the memory device. An example illustration is performed below in conjunction with FIG. 1.

FIG. 1 is a schematic distribution diagram illustrating a memory device according to examples of the present disclosure. The memory device comprises, but is not limited to, a DRAM memory. The illustration is performed using the DRAM memory as an example for ease of understanding. Configuration information for normal operations and trim information of the DRAM are stored in a non-volatile memory, and will be loaded into a rapidly accessible trim register during power on initialization. As the level of integration and a bit density of the DRAM increase, a larger capacity of or a larger number of trim registers is required (e.g., a size of 4 k bits). As shown in FIG. 1, a dashed line box 30 indicates an arrangement position of a trim register group, and the trim register group comprises a plurality of trim registers, increasing the area of the DRAM, which is not favorable to further miniaturization of the size of the memory device. It is to be noted that numerals 1 to 34 in FIG. 1 are used to indicate arrangement positions of functional circuits in the DRAM, and the particular functional circuits are not shown for simplicity. For example, a numeral 1 and a numeral 29 may indicate arrangement positions of non-volatile memories for storing the configuration information and the trim information.

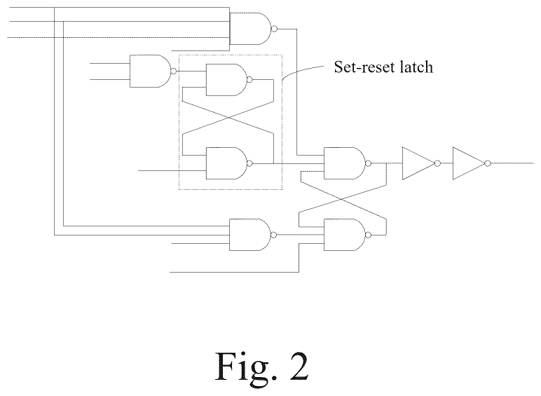

FIG. 2 is a schematic diagram illustrating a trim register according to examples of the present disclosure. With reference to FIG. 2, the trim register comprises a set-reset latch, and the loaded trim information may be latched to the set-reset latch (RS latch). The set-reset latch is consist of two NAND gates, and therefore has a larger area, causing the trim register to have a large area. The trim register further comprises a plurality of other NAND gates, which are used to realize functions such as power on initialization and test addressing respectively, causing the area of the trim register to be further increased.

Based on one or more of the above technical problems, examples of the present disclosure provide a memory device. The memory device may be a Random Access Memory (RAM), such as a Dynamic Random Access Memory (DRAM), a Synchronous DRAM (SDRAM), a Static RAM (SRAM), a Double Data Rate SDRAM (DDR SDRAM), a DDR2 SDRAM, a DDR3 SDRAM, a Phase-change RAM (PRAM), a Magnetic RAM (MRAM), a Resistive RAM (RRAM). The following illustration is performed by using only the DRAM as an example.

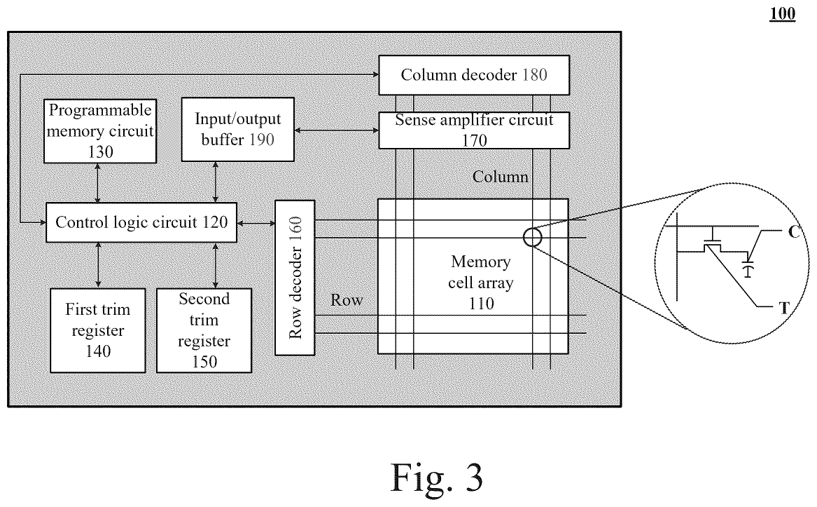

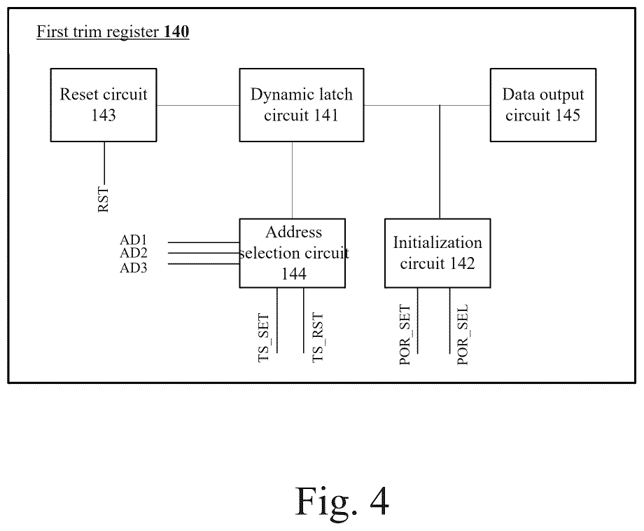

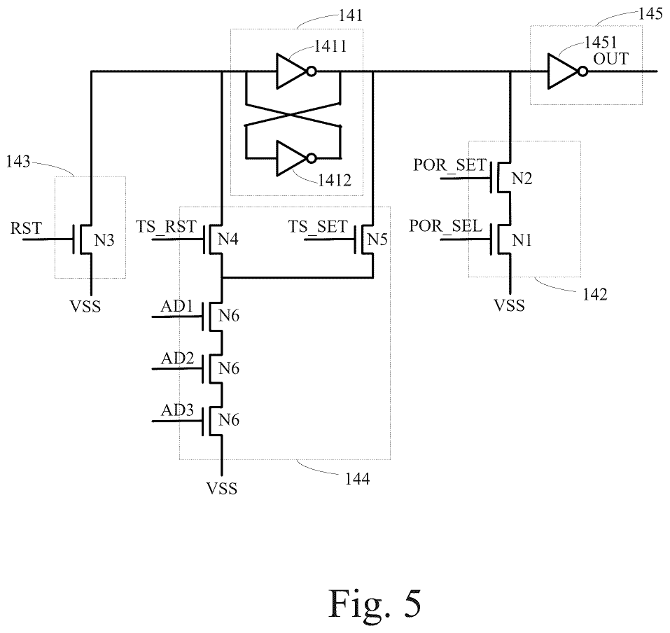

FIG. 3 is a schematic block diagram illustrating a memory device according to examples of the present disclosure. FIG. 4 is a schematic block diagram illustrating a first trim register according to examples of the present disclosure. FIG. 5 is a schematic circuit diagram illustrating the first trim register according to examples of the present disclosure. Example illustrations of the memory device and the first trim register provided by examples of the present disclosure are performed below in conjunction with FIG. 3 and FIG. 5.

With reference to FIG. 3, the memory device 100 comprises a memory cell array 110, the memory cell array 110 comprises a plurality of memory cells arranged in an array, and each memory cell comprises one Transistor (T) and one Capacitor (C). A main action principle of the memory cell is to use an amount of charge stored in the capacitor to represent whether a binary bit is 1 or 0.

The memory cell array 110 may be divided into a plurality of memory banks, each memory bank comprises a plurality of memory blocks, each memory block comprises a plurality of memory cell rows and a plurality of memory cell columns, each memory cell row is coupled with one corresponding word line, and each memory cell column is coupled with one corresponding bit line. The memory cell array 110 designates an address using a row and a column. By designating an intersection of the row and the column (by designating a row address and a column address of the DRAM), a memory controller may access each memory cell independently, and perform a read, write, or refresh operation on data stored in the memory cell.

Still with reference to FIG. 3, the memory device 100 further comprises a peripheral circuit coupled with the memory cell array 110. The peripheral circuit may write or read data to or from the memory cell array 110 in response to a command CMD and an address ADDR received from the memory controller, or may provide a control signal for refreshing the memory cell included in the memory cell array 110 for a row decoder 160 and a column decoder 180. In other words, the peripheral circuit may perform all operations to process the data stored in the memory cell array 110. The peripheral circuit may comprise: a control circuit corresponding to each memory block, such as a sense amplifier circuit 170 and a word line driver circuit (not shown); a control circuit corresponding to each memory bank, such as the row decoder 160 or the column decoder 180; and a control circuit corresponding to all the memory banks, such as an input/output buffer 190, a command buffer, a command decoder, an address buffer, or a mode register.

In some examples, with reference to FIG. 3, the peripheral circuit further comprises a programmable memory circuit 130 configured to store a plurality of trim information, wherein the plurality of trim information may be written to the programmable memory circuit 130 after a trim test and loaded into the first trim register 140 during power on initialization of the memory device 100. The programmable memory circuit 130 comprises at least one of a non-volatile memory such as a One Time Programmable (OTP) memory, or a Multi-Time Programmable (MTP) memory, wherein the OTP memory may comprise a fuse array or an antifuse array, etc. The programmable memory circuit 130 comprises a non-volatile memory, and therefore may avoid a loss of the trim information.

In some examples, with reference to FIG. 3, the peripheral circuit further comprises a first trim register 140 coupled with the programmable memory circuit 130 and comprising a dynamic latch circuit 141, wherein the first trim register 140 is configured to: load a first trim information of the plurality of trim information from the programmable memory circuit 130 in response to the memory device 100 entering a working mode; and latch the first trim information to the dynamic latch circuit 141.

In the examples of the present disclosure, the first trim register 140 may load the first trim information of the plurality of trim information from the programmable memory circuit 130 when the memory device 100 enters the working mode, and latch the loaded first trim information to the dynamic latch circuit 141 (i.e., a dynamic latch), thereby achieving a fast access of the first trim information. Typically, the dynamic latch is comprised of two inverters and has a small area. Accordingly, a circuit structure of the first trim register may be optimized, and the area of the first trim register may be reduced, which is favorable to further miniaturization of the size of the memory device.

In a particular example, with reference to FIG. 5, the dynamic latch circuit 141 comprises a first inverter 1411 and a second inverter 1412, an output end of the first inverter 1411 is coupled with an input end of the second inverter 1412, and an output end of the second inverter 1412 is coupled with an input end of the first inverter 1411.

It is to be noted that there may be one or more first trim registers 140 in the memory device 100, depending on a design of the memory device 100 in practical applications, and there is no particular limitation on the number of the first trim registers 140 in the examples of the present disclosure. The above working mode may be a mode entered by a chip normally after power on during practical use, while a test mode in the following may be accessing a program inside the chip through an interface before the chip is packaged, that is, in the test mode, the program or parameters inside the chip may be modified or debugged.

In some examples, with reference to FIGS. 3 and 4, the memory device 100 further comprises: a control logic circuit 120 coupled with the first trim register 140 and configured to: generate an initialization signal POR_SEL in response to the memory device 100 entering the working mode, wherein the first trim register 140 further comprises an initialization circuit 142 coupled with the dynamic latch circuit 141 and configured to: initialize the dynamic latch circuit 141 in response to the initialization signal POR_SEL.

In the examples of the present disclosure, the control logic circuit 120 may generate the initialization signal POR_SEL when the memory device 100 is powered on, and send the initialization signal POR_SEL to the initialization circuit 142. The initialization circuit 142 initializes the dynamic latch circuit 141 in response to the initialization signal POR_SEL, until the first trim information is latched to the dynamic latch circuit 141. In an implementation, the control logic circuit 120 may read the first trim information stored in the programmable memory circuit 130 and then load the read first trim information to the first trim register 140, and in an example implementation, the first trim information may be latched in the dynamic latch circuit 141.

In some examples, with reference to FIG. 5, the initialization circuit 142 comprises a first transistor N1, a first end of the first transistor N1 is coupled with the output end of the first inverter 1411, a second end of the first transistor N1 is coupled with a first supply end, and a control end of the first transistor N1 is configured to receive an initialization signal POR_SEL. The first transistor N1 includes, but is not limited to, an NMOS transistor, and the first supply end includes, but is not limited to, a ground end VSS. In the examples of the present disclosure, the illustration is performed with an example where the first transistor N1 is the NMOS transistor and the first supply end is the ground end VSS.

It is to be noted that the trim register is typically required to implement at least three functions: 1) data latch, wherein the trim information is required to be latched at a stable level; 2) Power On Reset (POR), wherein data is load from the non-volatile memory during power on, and this function does not require the trim register to be addressable; and 3) the test mode, wherein test trim information is input from the outside (i.e., loading the test trim information from the outside), and this function requires the trim register to be addressable, so as to select a target trim register from a plurality of trim registers.

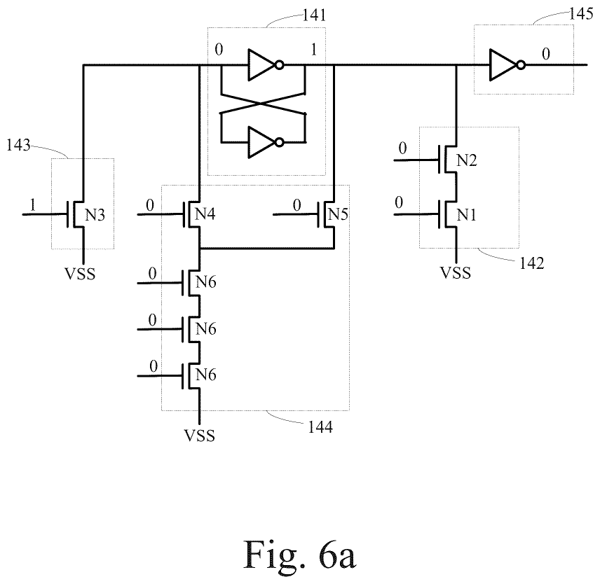

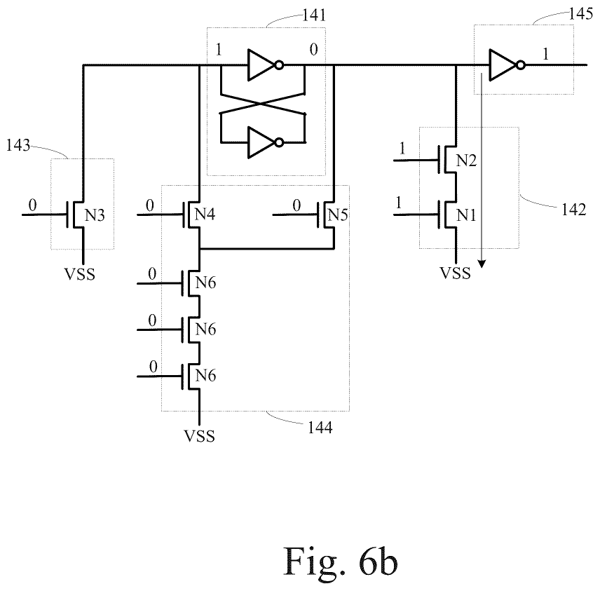

FIG. 6a and FIG. 6b are schematic diagrams illustrating latching of the trim information to the dynamic latch circuit 141 in the working mode according to examples of the present disclosure. Example illustrations of achieving data latching and power on initialization by the first trim register 140 provided by examples of the present disclosure are performed below in conjunction with FIG. 6a and FIG. 6b.

With reference to FIG. 6b, the control end of the first transistor N1 receives the initialization signal “1” (i.e., POR_SEL=1) and is on, the output end of the first inverter 1411 is coupled with the ground end VSS (as shown by the arrow in FIG. 6b) through the first transistor N1, and the output end of the first inverter 1411 is discharged to a low level “0”, thereby latching the first trim information “1” into the dynamic latch circuit 141. FIG. 6b illustrates an example process of latching the first trim information “1” to the dynamic latch circuit 141 during the power on initialization. However, in other examples, the first trim information “0” may also be latched to the dynamic latch circuit 141 during the power on initialization. The first trim information may be denoted by a binary symbol “0” or “1”.

In some examples, the initialization circuit 142 further comprises a second transistor N2, a first end of the second transistor N2 is coupled with the output end of the first inverter 1411, a second end of the second transistor N2 is coupled with the first end of the first transistor N1, and a control end of the second transistor N2 is configured to receive an initialization drive signal POR_SET. The second transistor N2 includes, but is not limited to, an NMOS transistor. In the examples of the present disclosure, the illustration is performed with an example where the second transistor N2 is the NMOS transistor.

With reference to FIG. 6b, the control end of the second transistor N2 receives the initialization drive signal POR_SET “1” (i.e., POR_SET=1) and is on, thereby driving the initialization circuit 142 to perform an initialization operation, wherein the initialization drive signal may be generated by the control logic circuit 120. Of course, in other examples, the second transistor N2 may be omitted, that is, the initialization circuit 142 comprises only the first transistor N1.

In practical applications, the memory device 100 comprises a plurality of first trim registers 140, and during the power on initialization, control ends of second transistors N2 of the plurality of first trim registers 140 may all be set to the high level “1”, so as to drive the initialization circuit 142 of each first trim register 140 to perform an initialization operation. The control end of the first transistor N1 of the selected first trim register 140 in the plurality of first trim registers 140 may be set to the high level “1”, so as to latch the first trim information “1” into the dynamic latch circuit 141 of the selected first trim register 140. The control end of the first transistor N1 of the unselected first trim register 140 in the plurality of first trim registers 140 is set to the low level “0”, so as to latch the first trim information “0” into the dynamic latch circuit 141 of the unselected first trim register 140.

In the examples of the present disclosure, the control logic circuit may generate the initialization signal when the memory device enters the working mode, and the initialization circuit initializes the dynamic latch circuit in response to the initialization signal, so that the first trim information may be latched to the dynamic latch circuit, which not only ensures that the data latch and power on initialization functions of the trim register are achieved normally, but also further reduces the area of the trim register, since the initialization circuit is consist of transistors, thereby providing a novel and compact first trim register.

In some examples, the first trim register 140 further comprises a data output circuit 145 configured to: output the first trim information. The data output circuit 145 may comprise at least one third inverter. As an example, FIG. 6b illustrates the data output circuit 145 comprising one third inverter 1451. As shown in FIG. 6b, the low level “0” at the output end of the first inverter 1411 is inverted into the high level “1” by the third inverter 1451, so as to output the first trim information “1” latched by the dynamic latch circuit 141.

In some examples, with reference to FIGS. 3 and 4, the control logic circuit 120 is further configured to: generate a reset signal RST in response to the memory device 100 entering the working mode; the first trim register 140 further comprises a reset circuit 143 coupled with the dynamic latch circuit 141 configured to: reset the dynamic latch circuit 141 in response to the reset signal RST prior to initializing the dynamic latch circuit 141.

In the examples of the present disclosure, the control logic circuit 120 may generate the reset signal RST when the memory device 100 is powered on and send the reset signal RST to the reset circuit 143. The reset circuit 143 resets the dynamic latching circuit 141 in response to the received reset signal RST, so as to clear information latched by the dynamic latch circuit 141 previously, avoiding affecting the first trim information latched subsequently. Here, the control logic circuit 120 may generate the initialization signal POR_SEL after the dynamic latch circuit 141 is reset, that is, the initialization signal POR_SEL is generated following the reset signal RST.

In some examples, the reset circuit 143 comprises a third transistor N3, a first end of the third transistor N3 is coupled with the input end of the first inverter 1411, a second end of the third transistor N3 is coupled with a second supply end, and a control end of the third transistor N3 is configured to receive the reset signal RST. The third transistor N3 includes, but is not limited to, an NMOS transistor, and the second supply end includes, but is not limited to, the ground end VSS. The second supply end and the first supply end may be the same supply end or different supply ends. In the examples of the present disclosure, the illustration is performed with an example where the third transistor N3 is the NMOS transistor and the second supply end is the ground end VSS.

With reference to FIG. 6a, the control end of the third transistor N3 receives the reset signal “1” (i.e., RST=1) and is on, the input end of the first inverter 1411 is coupled with the ground end VSS through the third transistor N3, and the input end of the first inverter 1411 is discharged to the low level “0” as shown in FIG. 6a, thereby resetting the dynamic latch circuit 141. It is to be noted that during the power on reset, control ends of third transistors N3 of the plurality of first trim registers 140 may all be set to the high level “1”, so as to reset the dynamic latch circuit 141 of each first trim register 140, and then the initialization operation is performed.

In the examples of the present disclosure, the control logic circuit may generate the reset signal when the memory device enters the working mode, and the reset circuit resets the dynamic latch circuit in response to the reset signal, so that the information latched by the dynamic latch circuit previously may be cleared, which not only ensures that the power on reset function of the trim register is achieved normally, but also further reduces the area of the trim register, since the reset circuit is consist of the third transistor.

In some examples, the first trim register 140 is further configured to: load a test trim information from the control logic circuit 120 in response to the memory device 100 entering a test mode; and latch the test trim information to the dynamic latch circuit 141.

In the examples of the present disclosure, the first trim register 140 may load the test trim information from the control logic circuit 120 when the memory device 100 enters the test mode, and latches the loaded test trim information to the dynamic latch circuit 141, wherein the test trim information may be input by the outside, e.g., by a tester. It may be understood that in the test mode, the tester inputs the test trim information for trimming the memory device 100, so as to improve the performance of the memory device 100, and the tester may further optimize the test trim information according to a trim result, until the memory device 100 passes the test. Then the optimized test trim information is kept in the programmable memory circuit 130, and the test trim information finally kept in the programmable memory circuit 130 comprise the plurality of trim information described above.

In some examples, the memory device 100 comprises a plurality of first trim registers 140, wherein the control logic circuit 120 is further configured to: generate an address signal AD1/AD2/AD3 and a test control signal in response to the memory device 100 entering the test mode; the first trim register 140 further comprises an address selection circuit 144 configured to: select at least one first trim register 140 from the plurality of first trim registers 140 in response to the address signal AD1/AD2/AD3; and latch the test trim information to the dynamic latch circuit 141 of the selected first trim register 140 in response to the test control signal.

In the examples of the present disclosure, the control logic circuit 120 may generate the address signal AD1/AD2/AD3 and the test control signal during the test of the memory device 100, and send the address signal AD1/AD2/AD3 and the test control signal to the address selection circuit 144. The address selection circuit 144 selects the respective first trim register 140 in response to the received address signal AD1/AD2/AD3, and latches the test trim information to the dynamic latch circuit 141 of the selected first trim register 140 in response to the test control signal.

In some examples, the address selection circuit 144 comprises a fourth transistor N4, a fifth transistor N5, and a sixth transistor N6, a first end of the fourth transistor N4 is coupled with the input end of the first inverter 1411, a first end of the fifth transistor N5 is coupled with the output end of the first inverter 1411, a second end of the fourth transistor N4 is coupled with a second end of the fifth transistor N5, and a control end of the fourth transistor or a control end of the fifth transistor N5 is configured to receive a test control signal; a first end of the sixth transistor N6 is coupled with a coupling node between the second end of the fourth transistor N4 and the second end of the fifth transistor N5, a second end of the sixth transistor N6 is coupled with a third supply end, and a control end of the sixth transistor N6 is configured to receive an address signal AD1/AD2/AD3. The fourth transistor N4, the fifth transistor N5, and the sixth transistor N6 each include, but are not limited to, an NMOS transistor; the third supply end includes, but is not limited to, the ground end VSS, and the third supply end, the second supply end, and the first supply end may be the same supply end or different supply ends. In the examples of the present disclosure, the illustration is performed with an example where the fourth transistor N4, the fifth transistor N5, and the sixth transistor N6 are all NMOS transistors and the third supply end is the ground end VSS.

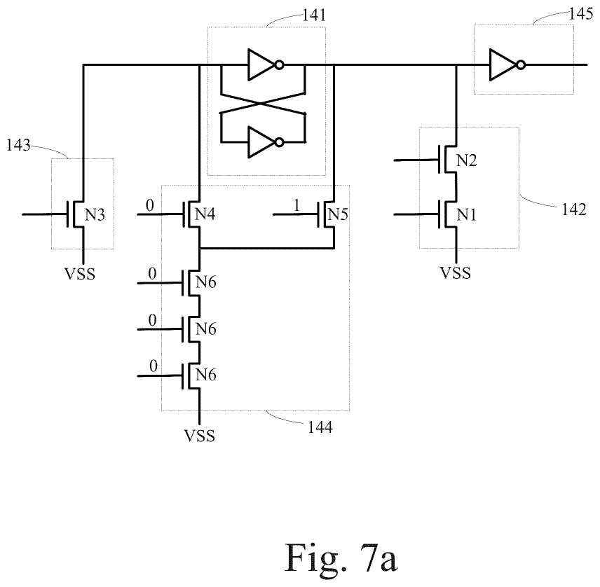

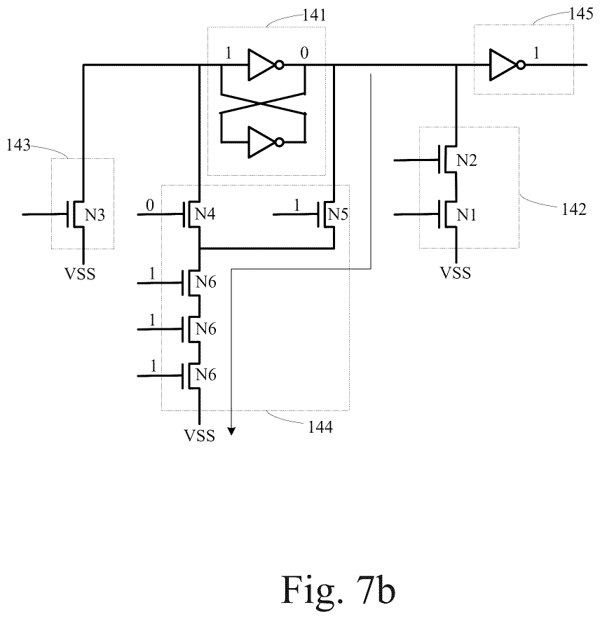

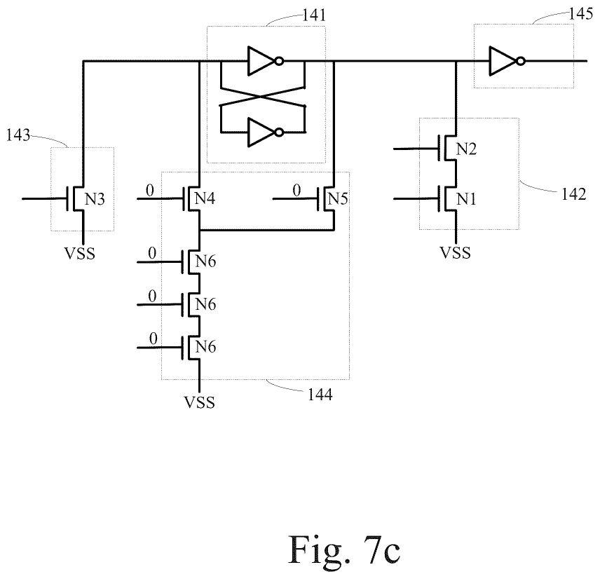

FIG. 7a to FIG. 7c are schematic diagrams illustrating latching of the trim information to the dynamic latch circuit 141 in the test mode according to examples of the present disclosure. An example illustration of achieving the test mode function by the first trim register 140 provided by examples of the present disclosure is performed below in conjunction with FIG. 7a to FIG. 7c.

With reference to FIG. 7a, the control end of the fifth transistor N5 receives the test control signal “1” (i.e., TS_SET=1) and is on. With reference to FIG. 7b, the control end of each sixth transistor N6 receives the address signal “1” (i.e., AD1/AD2/AD3=1) and is on, the output end of the first inverter 1411 is coupled with the ground end VSS through the fifth transistor N5 and a plurality of sixth transistors N6 connected in series (as shown by the arrow in FIG. 7b), and the output end of the first inverter 1411 is discharged to the low level “0”, thereby latching the first trim information “1” into the dynamic latch circuit 141. In this example, the fourth transistor N4 remains an off state.

In other examples, with reference to FIG. 5, the control end of the fourth transistor N4 receives the test control signal “1” (i.e., TS_SET=1) and is on. The control end of each sixth transistor N6 receives the address signal “1” and is on, the input end of the first inverter 1411 is coupled with the ground end VSS through the fourth transistor N4 and the plurality of sixth transistors N6 connected in series, and the input end of the first inverter 1411 is discharged to the low level “0”, thereby latching the first trim information “0” into the dynamic latch circuit 141. In this example, the fifth transistor N5 remains an off state.

It is to be noted that in the above example, the control end of the fourth transistor N4 or the fifth transistor N5 is set to “1” before setting the control end of each sixth transistor N6 set to “1”. In other examples, the control end of each sixth transistor N6 may also be set to “1” before setting the control end of the fourth transistor N4 or the fifth transistor N5 to “1”, that is, there is no particular limitation on a timing of the test control signal and the address selection signal in the examples of the present disclosure.

In practical applications, the address signal received by the selected first trim register 140 in the plurality of first trim registers 140 may be “111”, as shown in FIG. 7b, and the address signal received by the unselected first trim register 140 in the plurality of first trim registers 140 may be “000”, “001”, or “011”, etc., that is, the first trim register 140 is selected only if all the three sixth transistors N6 are on. As an example, three sixth transistors N6 are illustrated in FIG. 7a to FIG. 7c. However, the number of the sixth transistors N6 may be less or more than three depending on the number of bits of the address signal, and there is no particular limitation on the number of the sixth transistors N6 in the examples of the present disclosure.

After the test trim information is latched to the dynamic latch circuit 141 of the selected first trim register 140, the selection of the first trim register 140 may be canceled. As shown in FIG. 7c, control ends of the fourth transistor N4, the fifth transistor N5, and the sixth transistor N6 are set to “0”, so that all the control ends of the fourth transistor N4, the fifth transistor N5, and the sixth transistor N6 are off.

In the examples of the present disclosure, the control logic circuit may generate the address signal and the test control signal when the memory device enters the test mode, and the address selection circuit latches the test trim information to the dynamic latch circuit of the selected first trim register in response to the address signal and the test control signal, which not only ensures that the test mode function of the trim register is achieved normally, but also further reduces the area of the trim register, since the address selection circuit is consist of transistors.

In some examples, with reference to FIG. 3, the memory device 100 further comprises: a second trim register 150 coupled with the programmable memory circuit 130 and comprising a set-reset latch circuit, wherein the second trim register 150 is configured to: load a second trim information of the plurality of trim information from the programmable memory circuit 130 in response to the memory device 100 entering the working mode; and latch the second trim information to the set-reset latch circuit. A particular structure of the second trim register 150 may be referred to FIG. 2.

Typically, a plurality of trim registers are required to be configured in the memory device 100, so as to meet a capacity requirement of registering a plurality of trim information. In the examples of the present disclosure, through combined use of the first trim register 140 and the second trim register 150, on one hand, a total area occupied by the plurality of trim registers may be reduced; on the other hand, time for loading the trim information from the programmable memory circuit 130 during the power on initialization may be reduced.

In some examples, an area of the first trim register 140 is less than an area of the second trim register 150. Since a plurality of circuit modules of the first trim register 140 provided by the examples of the present disclosure are implemented by using transistors, and a plurality of circuit modules of the second trim register 150 are implemented by using NAND gates, the area of the first trim register 140 is less than the area of the second trim register 150.

Based on the memory device described above, examples of the present disclosure provide a trim register. The trim register comprises: a reset circuit, an initialization circuit, and a dynamic latch circuit, wherein the reset circuit and the initialization circuit are coupled with the dynamic latch circuit respectively; the reset circuit is configured to: reset the dynamic latch circuit; the initialization circuit is configured to: initialize the dynamic latch circuit, until a loaded trim information is latched to the dynamic latch circuit; the dynamic latch circuit is configured to: latch the trim information.

In some examples, the dynamic latch circuit comprises a first inverter and a second inverter, an output end of the first inverter is coupled with an input end of the second inverter, and an output end of the second inverter is coupled with an input end of the first inverter; the initialization circuit comprises a first transistor, a first end of the first transistor is coupled with the output end of the first inverter, a second end of the first transistor is coupled with a first supply end, and a control end of the first transistor is configured to receive an initialization signal.

In some examples, the initialization circuit further comprises a second transistor, a first end of the second transistor is coupled with the output end of the first inverter, a second end of the second transistor is coupled with the first end of the first transistor, and a control end of the second transistor is configured to receive an initialization drive signal.

In some examples, the reset circuit comprises a third transistor, a first end of the third transistor is coupled with the input end of the first inverter, a second end of the third transistor is coupled with a second supply end, and a control end of the second transistor is configured to receive a reset signal.

In some examples, the trim register further comprises an address selection circuit configured to: select the trim register; and latch test trim information to the dynamic latch circuit of the selected trim register.

In some examples, the address selection circuit comprises a fourth transistor, a fifth transistor, and a sixth transistor, a first end of the fourth transistor is coupled with the input end of the first inverter, a first end of the fifth transistor is coupled with the output end of the first inverter, a second end of the fourth transistor is coupled with a second end of the fifth transistor, and a control end of the fourth transistor or a control end of the fifth transistor is configured to receive a test control signal; a first end of the sixth transistor is coupled with a coupling node between the second end of the fourth transistor and the second end of the fifth transistor, a second end of the sixth transistor is coupled with a third supply end, and a control end of the sixth transistor is configured to receive an address signal.

In some examples, the trim register further comprises a data output circuit configured to: output the trim information.

In some examples, the data output circuit comprises at least one third inverter.

In the examples of the present disclosure, the trim register may be the first trim register in the memory device as described in any of the above examples, and the technical effects that can be realized by the first trim register as described in the above examples all can be realized by this trim register, which are no longer repeated one by one here. With respect to the various functions of the first trim register in the above examples, example implementations of the modules therein have been described in detail in the relevant device examples, which are no longer set forth in detail here. It is to be emphasized that the trim register is applicable to a variety of chips known in this field.

Based on the above-mentioned memory device, examples of the present disclosure provide an operation method of a memory device.

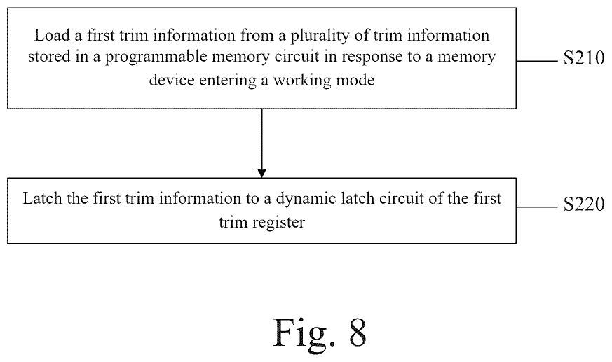

FIG. 8 is a flow diagram illustrating an operation method of a memory device according to examples of the present disclosure. The operation method at least comprises the following:

S210: loading a first trim information from the plurality of trim information stored in the programmable memory circuit in response to the memory device entering the working mode; and

S220: latching the first trim information to the dynamic latch circuit of the first trim register.

In some examples, the operation method further comprises: generating the initialization signal in response to the memory device entering the working mode; S220 comprises: initializing the dynamic latch circuit in response to the initialization signal.

In some examples, the operation method further comprises: generating the reset signal in response to the memory device entering the working mode; and resetting the dynamic latch circuit in response to the reset signal prior to initializing the dynamic latch circuit.

In some examples, the operation method further comprises: loading test trim information from the control logic circuit in response to the memory device entering the test mode; and latching the test trim information to the dynamic latch circuit.

In some examples, the operation method further comprises: generating an address signal and a test control signal in response to the memory device entering the test mode; the latching the test trim information to the dynamic latch circuit comprises: selecting at least one first trim register from the plurality of first trim registers in response to the address signal; and latching the test trim information to the dynamic latch circuit of the selected first trim register in response to the test control signal.

In some examples, the operation method further comprises: loading second trim information from the plurality of trim information stored in the programmable memory circuit in response to the memory device entering the working mode; and latching the second trim information to the set-reset latch circuit of the second trim register.

In the examples of the present disclosure, the operation method of a memory device may be performed by the control logic circuit in the memory device as described in any of the above examples, and the technical effects that can be realized by the memory device in the above examples all can be realized by this operation method of a memory device, which are no longer repeated one by one here. An example implementation of each operation of the operation method in the above examples is described in detail in relevant device examples, which is no longer set forth in detail here.

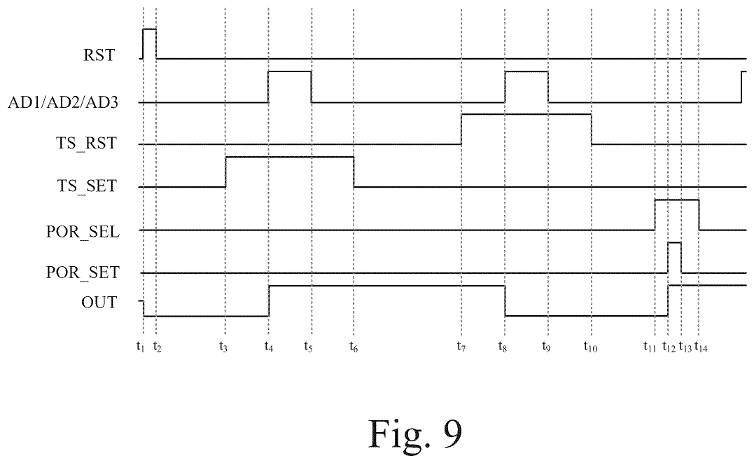

FIG. 9 is a diagram illustrating an operation timing of a memory device according to examples of the present disclosure. The operation method of a memory device provided by the examples of the present disclosure will be described in detail below in conjunction with the timing diagram in FIG. 9 and the first trim register in FIG. 5.

During time from t₁ to t₂, the third transistor N3 in the reset circuit 143 is on in response to the reset signal “1” (i.e., RST=1), and the input end of the first inverter 1411 is discharged to the low level “0”, thereby resetting the dynamic latch circuit 141, whereby the data output circuit 145 outputs the low level “0” (i.e., OUT=0).

During time from t₃ to t₆, the fifth transistor N5 in the address selection circuit 144 is on in response to the test control signal “1” (TS_SET=1), and during time from t₄ to t₅, each sixth transistor N6 in the address selection circuit 144 is on in response to the address signal “1” (i.e., AD1/AD2/AD3=1). The output end of the first inverter 1411 is discharged to the low level “0”, thereby latching the test trim information “1” to the dynamic latch circuit 141, and the data output circuit 145 switches from the low level “0” to the high level “1” at t₄, that is, the data output circuit 145 outputs the test trim information “1” (i.e., OUT=1). In this example, the fourth transistor N4 remains an off state.

During time from t₇ to t₁₀, the fourth transistor N4 in the address selection circuit 144 is on in response to the test control signal “1” (TS_SET=1), and during time from t₈ to t9, each sixth transistor N6 in the address selection circuit 144 is on in response to the address signal “1” (i.e., AD1/AD2/AD3=1). The input end of the first inverter 1411 is discharged to the low level “0”, thereby latching the test trim information “0” to the dynamic latch circuit 141, and the data output circuit 145 switches from the high level “1” to the low level “0” at t₈, that is, the data output circuit 145 outputs the test trim information “0” (i.e., OUT=0). In this example, the fifth transistor N5 remains an off state.

During time from t11 to t14, the first transistor N1 in the initialization circuit 142 is on in response to the initialization signal “1” (POR_SEL=1), and during time from t₁₂ to t₁₃, the second transistor N2 in the initialization circuit 142 is on in response to the initialization drive signal “1” (i.e., POR_SET=1). The output end of the first inverter 1411 is discharged to the low level “0”, thereby latching the first trim information “1” to the dynamic latch circuit 141, and the data output circuit 145 switches from the low level “0” to the high level “1” at t₁₂, that is, the data output circuit 145 outputs the first trim information “1” (i.e., OUT=1).

Based on the memory device described above, examples of the present disclosure provide a memory system, comprising: one or more memory devices as described above; and a memory controller coupled to the one or more memory devices and configured to control the one or more memory devices.

Based on the memory system described above, examples of the present disclosure provide an electronic apparatus, comprising the memory system described above.

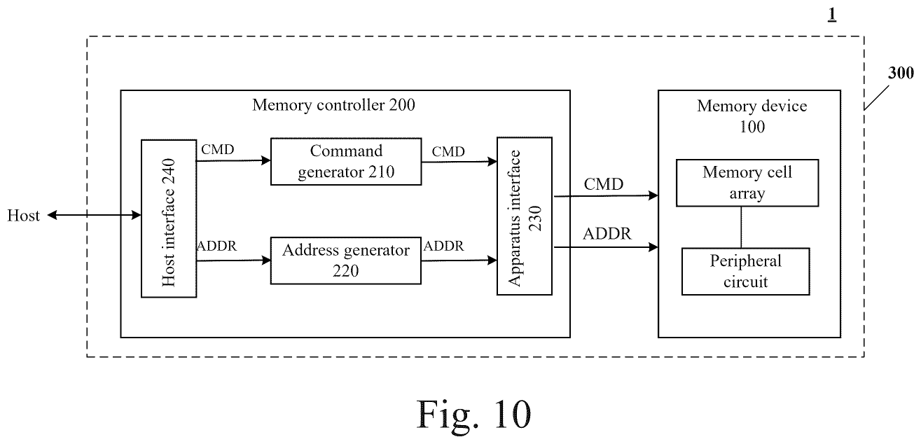

FIG. 10 is a schematic block diagram illustrating an electronic apparatus according to examples of the present disclosure. Example illustrations of the electronic apparatus and the memory system provided by examples of the present disclosure are performed below in conjunction with FIG. 10. The electronic apparatus 1 may be a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having memory devices therein.

As shown in FIG. 10, the electronic apparatus 1 may comprise a host HOST and a memory system 300, and the memory system 300 is provided with one or more memory devices 100 and a memory controller 200. The host HOST may be a processor of the electronic apparatus 1 (such as a Central Processing Unit (CPU), or a System on Chip (SoC) (e.g., an Application Processor (AP))). The host HOST may be configured to send or receive data to or from the memory device 100. The memory controller 200 is coupled to the memory device 100 and the host HOST, and configured to control the memory device 100. The memory controller 200 can manage data stored in the memory device 100 and communicate with the host HOST.

The memory controller 200 may be configured to control operations of the memory device 100, such as read, erase, write, and refresh operations. In some implementations, the memory controller 200 is further configured to process an Error Correction Code (ECC) with respect to data read from or written to the memory device 100. The memory controller 200 may further execute any other suitable functions, e.g., formatting the memory device 100.

In some particular examples, the memory controller 200 and one or more memory devices 100 may be integrated into various types of storage apparatuses. For example, the memory controller 200 may be integrated into a north bridge of a computer mainboard or directly integrated in the interior of a CPU of a computer, and the plurality of memory devices 100 may be integrated into a memory module. That is, the memory system 300 may be implemented and packaged into different types of end electronic products.

The memory controller 200 may send or receive data to or from the host HOST, and may send a command CMD and an address ADDR to the memory device 100. The memory controller 200 may comprise a command generator 210, an address generator 220, an apparatus interface 230, and a host interface 240. The host interface 240 may receive the command CMD and the address ADDR from the host HOST; and the command generator 210 may generate an access command, a refresh command, etc. by decoding the command CMD received from the host HOST, and may provide the access command and the refresh command to the memory device 100 through the apparatus interface 230. The access command may be a signal that instructs the memory device 100 to write or read data by accessing a row of the memory cell array corresponding to the address ADDR. The refresh command may be a signal that instructs the memory device 100 to read and re-write data by accessing the row of the memory cell array corresponding to refreshing the address ADDR.

The address generator 220 in the memory controller 200 may generate a row address and a column address to be accessed in the memory cell array by decoding the address ADDR received from the host interface 240. Furthermore, the memory device 100 may generate an address of a memory bank to be accessed when the memory cell array comprises a plurality of memory banks.

Moreover, the memory controller 200 may control memory operations such as write and read, by providing various signals to the memory device 100 via the apparatus interface 230. For example, the memory controller 200 may provide a write command to the memory device 100. The write command is used for instructing the memory device 100 to perform a write operation to store data in the memory device 100.

The features disclosed in several device examples provided by the present disclosure may be combined arbitrarily to obtain a new device example in the case of no conflicts.

The methods disclosed in several method examples provided by the present disclosure may be combined freely to obtain new method examples in case of no conflicts.

It is to be understood that “one example” and “an example” mentioned throughout the specification mean that specific features, structures or characteristics related to the example is included in at least one example of the present disclosure. Therefore, “in one example” or “in an example” appearing at any place throughout specification does not always refer to the same example. In addition, these specific features, structures or characteristics may be combined in one or more examples in any proper manner. It is to be understood that, in various examples of the present disclosure, the sequence number of each process does not mean the sequence of execution. The execution sequence of each process should be determined by its functions and internal logic, which should not constitute any limitation on the implementation process of the examples of the present disclosure. The above sequence numbers of the examples of the present disclosure are used for description only, and do not represent advantage and disadvantage of the examples.

It is to be noted that the term “include”, “comprise” or any other variant thereof is intended to cover nonexclusive inclusions herein, so that a process, method, object or apparatus comprising a series of components not only comprises those components but also comprises other components which are not clearly listed or further comprises components intrinsic to the process, the method, the object or the apparatus. In the case of no more limitations, a element defined by the statement “including a/an . . . ” does not exclude the existence of another identical element in a process, method, object or apparatus comprising the element.

The above descriptions are merely implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A memory device, comprising:
a programmable memory circuit configured to store a plurality of trim information; and
a first trim register coupled with the programmable memory circuit, the first trim register comprising a dynamic latch circuit, wherein the first trim register is configured to:
load a first trim information of the plurality of trim information from the programmable memory circuit in response to the memory device entering a working mode; and
latch the first trim information to the dynamic latch circuit.

2. The memory device of claim 1, further comprising:
a control logic circuit coupled with the first trim register, and configured to generate an initialization signal in response to the memory device entering the working mode,
wherein the first trim register further comprises an initialization circuit coupled with the dynamic latch circuit and configured to initialize the dynamic latch circuit in response to the initialization signal.

3. The memory device of claim 2, wherein
the control logic circuit is further configured to generate a reset signal in response to the memory device entering the working mode; and
the first trim register further comprises a reset circuit coupled with the dynamic latch circuit and configured to reset the dynamic latch circuit in response to the reset signal prior to initializing the dynamic latch circuit.

4. The memory device of claim 3, wherein the dynamic latch circuit comprises a first inverter and a second inverter, an output end of the first inverter is coupled with an input end of the second inverter, and an output end of the second inverter is coupled with an input end of the first inverter; and
the initialization circuit comprises a first transistor, a first end of the first transistor is coupled with the output end of the first inverter, a second end of the first transistor is coupled with a first supply end, and a control end of the first transistor is configured to receive the initialization signal.

5. The memory device of claim 4, wherein the initialization circuit further comprises a second transistor, a first end of the second transistor is coupled with the output end of the first inverter, a second end of the second transistor is coupled with the first end of the first transistor, and a control end of the second transistor is configured to receive an initialization drive signal.

6. The memory device of claim 4, wherein the reset circuit comprises a third transistor, a first end of the third transistor is coupled with the input end of the first inverter, a second end of the third transistor is coupled with a second supply end, and a control end of the third transistor is configured to receive the reset signal.

7. The memory device of claim 2, wherein the first trim register is further configured to:
load a test trim information from the control logic circuit in response to the memory device entering a test mode; and
latch the test trim information to the dynamic latch circuit.

8. The memory device of claim 7, further comprising a plurality of first trim registers, wherein the control logic circuit is further configured to generate an address signal and a test control signal in response to the memory device entering the test mode; and
the first trim register further comprises an address selection circuit configured to:
select at least one first trim register from the plurality of first trim registers in response to the address signal; and
latch the test trim information to the dynamic latch circuit of the selected first trim register in response to the test control signal.

9. The memory device of claim 8, wherein the dynamic latch circuit comprises a first inverter and a second inverter, an output end of the first inverter is coupled with an input end of the second inverter, and an output end of the second inverter is coupled with an input end of the first inverter;
the address selection circuit comprises a fourth transistor, a fifth transistor, and a sixth transistor, a first end of the fourth transistor is coupled with the input end of the first inverter, a first end of the fifth transistor is coupled with the output end of the first inverter, a second end of the fourth transistor is coupled with a second end of the fifth transistor, and a control end of the fourth transistor or a control end of the fifth transistor is configured to receive the test control signal; and
a first end of the sixth transistor is coupled with a coupling node between the second end of the fourth transistor and the second end of the fifth transistor, a second end of the sixth transistor is coupled with a third supply end, and a control end of the sixth transistor is configured to receive the address signal.

10. The memory device of claim 1, further comprising:
a second trim register coupled with the programmable memory circuit and comprising a set-reset latch circuit, wherein the second trim register is configured to:
load second trim information of the plurality of trim information from the programmable memory circuit in response to the memory device entering the working mode; and
latch the second trim information to the set-reset latch circuit.

11. The memory device of claim 10, wherein an area of the first trim register is less than an area of the second trim register.

12. The memory device of claim 1, further comprising a dynamic random access memory.

13. A trim register, comprising:
a reset circuit, an initialization circuit, and a dynamic latch circuit,
wherein the reset circuit and the initialization circuit are coupled with the dynamic latch circuit, respectively;
the reset circuit is configured to reset the dynamic latch circuit;
the initialization circuit is configured to initialize the dynamic latch circuit, until a loaded trim information is latched to the dynamic latch circuit; and
the dynamic latch circuit is configured to latch the trim information.

14. The trim register of claim 13, wherein the dynamic latch circuit comprises a first inverter and a second inverter, an output end of the first inverter is coupled with an input end of the second inverter, and an output end of the second inverter is coupled with an input end of the first inverter; and
the initialization circuit comprises a first transistor, a first end of the first transistor is coupled with the output end of the first inverter, a second end of the first transistor is coupled with a first supply end, and a control end of the first transistor is configured to receive an initialization signal.

15. The trim register of claim 14, wherein the initialization circuit further comprises a second transistor, a first end of the second transistor is coupled with the output end of the first inverter, a second end of the second transistor is coupled with the first end of the first transistor, and a control end of the second transistor is configured to receive an initialization drive signal.

16. The trim register of claim 14, wherein the reset circuit comprises a third transistor, a first end of the third transistor is coupled with the input end of the first inverter, a second end of the third transistor is coupled with a second supply end, and a control end of the third transistor is configured to receive a reset signal.

17. The trim register of claim 14, further comprising an address selection circuit configured to:
select the trim register; and
latch a test trim information to the dynamic latch circuit of the selected trim register.

18. The trim register of claim 17, wherein the address selection circuit comprises a fourth transistor, a fifth transistor, and a sixth transistor, a first end of the fourth transistor is coupled with the input end of the first inverter, a first end of the fifth transistor is coupled with the output end of the first inverter, a second end of the fourth transistor is coupled with a second end of the fifth transistor, and a control end of the fourth transistor or a control end of the fifth transistor is configured to receive a test control signal; and
a first end of the sixth transistor is coupled with a coupling node between the second end of the fourth transistor and the second end of the fifth transistor, a second end of the sixth transistor is coupled with a third supply end, and a control end of the sixth transistor is configured to receive an address signal.

19. The trim register of claim 13, further comprising a data output circuit configured to output the trim information.

20. A memory system, comprising:
a memory device, comprising:
a programmable memory circuit configured to store a plurality of trim information; and
a first trim register coupled with the programmable memory circuit, the first trim register comprising a dynamic latch circuit, wherein the first trim register is configured to:
load a first trim information of the plurality of trim information from the programmable memory circuit in response to a memory device entering a working mode; and
latch the first trim information to the dynamic latch circuit; and
a memory controller coupled to the memory device and configured to control the memory device.
